(19) United States
(12) Patent Application Publication
(10) Pub. No.: US 2025/0383415 A1
(43) Pub. Date: Dec. 18, 2025

(54) HYPERPOLARISATION METHOD AND DEVICE

(71) Applicants: UNIVERSITE CLAUDE BERNARD LYON 1, Villeurbanne Cedex (FR); CENTRE NATIONAL DE LA RECHERCHE SCIENTIFIQUE, Paris (FR); ECOLE NORMALE SUPERIEURE DE LYON, Lyon (FR)

(72) Inventors: Sami JANNIN, Echandens (CH); Konstantin IVANOV; Quentin STERN, Evanston, IL (US); Morgan CEILLIER, Montpellier (FR); Stuart ELLIOTT, Leytonstone (GB)

(73) Assignees: UNIVERSITE CLAUDE BERNARD LYON 1, Villeurbanne Cedex (FR); CENTRE NATIONAL DE LA RECHERCHE SCIENTIFIQUE, Paris (FR); ECOLE NORMALE SUPERIEURE DE LYON, Lyon (FR)

(21) Appl. No.: 18/879,934

(22) PCT Filed: Jun. 28, 2023
(86) PCT No.: PCT/EP2023/067667

§ 371 Date: Dec. 30, 2024

(30) Foreign Application Priority Data
Jun. 29, 2022 (FR) 2206579

(51) Int. Cl. G01R 33/28

(52) U.S. Cl. CPC G01R 33/282

(57) ABSTRACT

An inversion chamber, including at least one magnetization element located at least partially inside a magnetic screen, referred to as the at least one internal magnetization element, and at least partially surrounding an inversion portion, wherein the at least one internal magnetization element is arranged to create an inversion magnetic field, the main component of which is along a Z direction and inverts as it travels through the inside of the inversion portion so as to transfer, within the inversion portion, the hyperpolarization from a first type of nuclear spins to a second type of nuclear spins, with scalar coupling between the nuclear spins, during a solution flow with non-zero velocity in the inversion portion from the chamber inlet to the chamber outlet. Also, a device including this chamber and a method implemented by such a device.

### TECHNICAL FIELD

The present invention relates to an inversion chamber, a hyperpolarization device comprising such a chamber, and a method implemented by such a device.

Such a device enables a user to hyperpolarize a solution quickly and

easily. The field of the invention is more particularly, but not limited to, that of hyperpolarized solutions for medical imaging.

### PRIOR ART

Dynamic nuclear polarization (DNP) processes are known, as for example described in WO200826937 from GE HEALTHCARE AS.

The production of metabolites with hyperpolarized ¹³C is enabling new applications in magnetic resonance imaging (MRI).

Hyperpolarized ¹³C-pyruvate is used in magnetic resonance imaging (MRI) applications. It can be obtained by dissolution dynamic nuclear polarization (dDNP). The most common method uses the trityl radical as a polarizing agent to directly polarize ¹³C. Hyperpolarized ¹³C can be prepared for MRIs with the SpinLab (GE Healthcare) using the trityl radical. With the trityl radical, hyperpolarized sample preparation time exceeds 60 min.

It is also possible to polarize ¹H nuclei and transfer the polarization to solid-state ¹³C by cross-polarization. This method is fast (less than 20 min), but relies on highly complex instrumentation. WO2013153101 from BRUKER BIOSPIN AG describes such a method.

The aim of the present invention is to propose a hyperpolarization device or method that is both fast and simple to implement, thus combining two technical advantages that the prior art is unable to combine, as well as a chamber for such a hyperpolarization device or method.

### DISCLOSURE OF THE INVENTION

This objective is achieved with a hyperpolarization method, comprising providing a solution in the liquid state comprising:
a first type of nuclear spins that are hyperpolarized and with a first gyromagnetic ratio and
a second type of nuclear spins with a second gyromagnetic ratio; the solution being supplied to an inversion chamber so that this solution circulates in the form of a solution flow within a conduit, a portion of which, called the inversion portion, passes through the inversion chamber;
the inversion chamber comprising an inlet through which the solution flow enters and an outlet through which the solution flow exits; the inversion chamber preferably comprising a magnetic screen surrounding the inversion portion so as to isolate the inversion portion from ambient magnetic fields around the magnetic screen;
the method further comprising:
creation, by at least one magnetization means (preferably located at least partially inside the magnetic screen), called at least one internal magnetization means, of an inversion magnetic field the main component of which is along a direction Z and inverts as it travels through the inside of the inversion portion so as to transfer, within the inversion portion, the hyperpolarization from the first type of nuclear spins to the second type of nuclear spins during a solution flow with non-zero velocity in the inversion portion from the chamber inlet to the chamber outlet.

The nuclear spins of both types of nuclear spins are preferably coupled by scalar spin-spin coupling in one or more molecules of the solution.

The inversion portion can be straight.

The at least one internal magnetization means may comprise, at least partially within the magnetic screen, a pair of internal magnetization means at least partially surrounding or framing or skirting the inversion portion. Each internal magnetization means:
can produce a magnetic field that is constant over time and is opposite to the field of the other internal magnetization means, the sum of the fields of these two internal magnetization means inverting within, preferably at the center of, the inversion portion, and/or
may comprise or be an internal solenoid, the at least one internal magnetization means thus comprising, at least partially within the magnetic screen, a pair of internal solenoids:
preferably supplied by currents with opposite directions of rotation and/or
preferably with opposing leakage fields.

The at least one internal magnetization means may comprise, at least partially within the magnetic screen, multiple internal solenoids, at least partially surrounding the inversion portion and connected by current divider bridges, the internal solenoids being separated into two assemblies of internal solenoids:
supplied by currents with opposite directions of rotation and/or
with opposing leakage fields.

Preferably, there is no gap between the two internal solenoid assemblies.

The current divider bridges may comprise resistors which can be varied via an adjustment interface, the method according to the invention preferably comprising a variation of the resistors of the divider bridges via this interface so as to adjust or optimize the magnetic field inversion profile.

The method according to the invention may comprise the use of a magnetization means, called an external inlet magnetization means, at least partially outside the magnetic screen and extending at least as far as the inlet of the inversion chamber, and a magnetization means, called an external outlet magnetization means, at least partially outside the magnetic screen and extending at least as far as the outlet of the inversion chamber, each external magnetization means maintaining within the conduit an input magnetic field at the inlet of the inversion chamber and an output magnetic field at the outlet of the inversion chamber.

Preferably, each external magnetization means surrounds or frames or skirts at least part of the at least one internal magnetization means.

Preferably:
an upstream magnetization means surrounds the conduit continuously between:
a zone which is both outside the magnetic screen and outside the external inlet magnetization means, and
a zone which is both outside the magnetic screen and inside the external inlet magnetization means, and/or
a downstream magnetization means surrounds the conduit continuously between:
a zone which is both outside the magnetic screen and outside the external outlet magnetization means, and
a zone which is both outside the magnetic screen and inside the external outlet magnetization means.

Each external inlet or outlet magnetization means can surround or frame or skirt a junction zone between:
a part of the conduit penetrating the external magnetization means, respectively inlet or outlet, while being surrounded by the magnetization means, respectively upstream or downstream, and
a part of the conduit surrounded or framed or skirted by the at least one internal magnetization means and penetrating the magnetic screen through the inlet or outlet of the inversion chamber respectively.

Each external magnetization means may comprise or be an external solenoid.

Each external magnetization means may comprise or be an external solenoid, each external solenoid preferably being carried around the conduit, surrounding the conduit, by means of an external support piece which:
on the conduit side, is not in contact with the conduit, and/or
on the side of each external solenoid, comprises reliefs arranged to accommodate and position the turns of each external solenoid.

The at least one internal magnetization means may be at least one internal solenoid.

The at least one internal magnetization means may be at least one internal solenoid, each internal solenoid being carried at least in part by the inversion portion, at least partially surrounding the inversion portion, via an internal support piece which:
on the conduit side, is in contact with the conduit, and/or
on the side of each internal solenoid, comprises reliefs arranged to accommodate and position the turns of each internal solenoid along the conduit.

The method according to the invention may further comprise supplying the solution, after passing through the inversion chamber, to a nuclear magnetic resonance (NMR) spectrometer or magnetic resonance imaging (MRI) device via the conduit.

The inversion magnetic field can have a single component in the inversion portion, which runs in the direction Z and inverts as it travels through the inversion portion.

The supply of solution to the inversion chamber may comprise a supply of solution from a DNP (Dynamic Nuclear Polarization) device connected to the conduit, and/or from any other device capable of producing and/or supplying a solution comprising both types of spin.

The inversion portion and/or conduit is preferably a capillary whose largest dimension, perpendicular to the solution flow, is less than 5 mm.

In the inversion portion, the inversion magnetic field is preferably between 0 mT and 0.1 mT in absolute value along the direction Z.

The first type of nuclear spins may have a higher gyromagnetic ratio than the second type.

According to still another aspect of the present invention, an inversion chamber is proposed, comprising:
an inlet arranged so that a flow of a solution in the liquid state comprising:
a first type of nuclear spins that are hyperpolarized and with a first gyromagnetic ratio and
o a second type of nuclear spins with a second gyromagnetic ratio, enters the chamber through this inlet;
an outlet arranged so that the solution flow leaves the chamber through this outlet the inlet and outlet being arranged so that this solution flows according to the solution flow within a conduit, a portion of which, called the inversion portion, passes through the inversion chamber;
the chamber further comprising:
preferably a magnetic screen surrounding the inversion portion so as to isolate the inversion portion from ambient magnetic fields around the magnetic screen;
at least one magnetization means (preferably located at least partially inside the magnetic screen), called at least one internal magnetization means, arranged to create an inversion magnetic field the main component of which is along a direction Z and inverts as it travels through the inside of the inversion portion so as to transfer, within the inversion portion, the hyperpolarization from the first type of nuclear spins to the second type of nuclear spins during a solution flow with non-zero velocity in the inversion portion from the chamber inlet to the chamber outlet.

The nuclear spins of both types of nuclear spins are preferably coupled by scalar spin-spin coupling in one or more molecules of the solution. The inversion portion can be straight.

The at least one internal magnetization means may comprise, at least

partially within the magnetic screen, a pair of internal magnetization means at least partially surrounding or framing or skirting the inversion portion. Each internal magnetization means:
can be arranged to produce a magnetic field that is constant over time and is opposite to the field of the other internal magnetization means, so that the sum of the fields of these two internal magnetization means inverts within, preferably at the center of, the inversion portion, and/or
may comprise or be an internal solenoid, the at least one internal magnetization means thus comprising, at least partially within the magnetic screen, a pair of internal solenoids, with preferably:
the chamber may further comprise a power supply arranged to supply the two internal solenoids with currents of opposite direction of rotation, and/or
the leakage fields of the two opposing internal solenoids.

The at least one internal magnetization means may comprise, at least partially within the magnetic screen, multiple internal solenoids, at least partially surrounding the inversion portion and connected by current divider bridges, the internal solenoids being separated into two assemblies of internal solenoids, the chamber further comprising a power supply arranged to power the two assemblies of internal solenoids:
by currents with opposite directions of rotation and/or
so that the leakage fields of the two assemblies of internal solenoids oppose each other.

The inversion chamber according to the invention might not comprise a gap between the two internal solenoid assemblies.

The current divider bridges may comprise resistors which can be varied via an adjustment interface, said adjustment interface being arranged to vary the resistors of the divider bridges via this interface so as to adjust or optimize the magnetic field inversion profile.

The inversion chamber according to the invention may comprise the use of a magnetization means, called an external inlet magnetization means, at least partially outside the magnetic screen and extending at least as far as the inlet of the inversion chamber, and a magnetization means, called an external outlet magnetization means, at least partially outside the magnetic screen and extending at least as far as the outlet of the inversion chamber, each external magnetization means maintaining within the conduit an input magnetic field at the inlet of the inversion chamber and an output magnetic field at the outlet of the inversion chamber.

Each external magnetization means may surround or frame or skirt at least part of the at least one internal magnetization means.

The inversion chamber according to the invention may further comprise:
an upstream magnetization means which surrounds the conduit continuously between:
a zone which is both outside the magnetic screen and outside the external inlet magnetization means, and
a zone which is both outside the magnetic screen and inside the external inlet magnetization means, and/or
a downstream magnetization means which surrounds the conduit continuously between:
a zone which is both outside the magnetic screen and outside the external outlet magnetization means, and
a zone which is both outside the magnetic screen and inside the external outlet magnetization means.

Each external inlet or outlet magnetization means can surround or frame or skirt a junction zone between:
a part of the conduit penetrating the external magnetization means, respectively inlet or outlet, while being surrounded by the magnetization means, respectively upstream or downstream, and
a part of the conduit surrounded or framed or skirted by the at least one internal magnetization means and penetrating the magnetic screen through the inlet or outlet of the inversion chamber respectively.

Each external magnetization means may comprise or be an external solenoid.

Each external solenoid can be carried around the conduit, surrounding the conduit, via an external support piece which:
on the conduit side, is not in contact with the conduit, and/or
on the side of each external solenoid, comprises reliefs arranged to accommodate and position the turns of each external solenoid.

The at least one internal magnetization means may be at least one internal solenoid.

Each internal solenoid can be carried at least in part by the inversion portion, at least partially surrounding the inversion portion, via an internal support piece which:
on the conduit side, is in contact with the conduit, and/or
on the side of each internal solenoid, comprises reliefs arranged to accommodate and position the turns of each internal solenoid along the conduit.

The inversion chamber according to the invention can be arranged so that the inversion magnetic field has, in the inversion portion, a single component which runs in the direction Z and which inverts as it travels through the inversion portion.

The inversion portion and/or the conduit may be a capillary whose largest dimension, perpendicular to the solution flow, is less than 5 mm.

The inversion chamber according to the invention can be arranged so that, in the inversion portion, the inversion magnetic field lies, in absolute value along the direction Z, at least between 0 mT and 0.1 mT.

The first type of nuclear spins may have a higher gyromagnetic ratio than the second type.

According to still another aspect of the present invention, a hyperpolarization device is proposed, comprising:
An inversion chamber according to the invention,
A device arranged to deliver the solution to the inlet of the inversion chamber through the conduit.

The device according to the invention may further comprise a nuclear magnetic resonance (NMR) spectrometer or a magnetic resonance imaging (MRI) device connected to the inversion chamber outlet via the conduit

The device arranged to provide the solution may comprise:
a dynamic nuclear polarization device DNP connected to the conduit, and/or
any other device capable of producing and/or supplying a solution comprising both types of spin.

### DESCRIPTION OF THE FIGURES AND EMBODIMENTS

Other benefits and features shall become evident upon examining the detailed description of entirely non-limiting embodiments and implementations, and from the following enclosed drawings:

FIG. 1 shows the common features of various embodiments 100, 200, 300, 400, 500 of hyperpolarization devices according to the invention, distinguished by the embodiment of inversion chamber 2 comprised in the 100, 200, 300, 400 or 500 device respectively,

FIG. 2 shows, in parts a) and b), a first embodiment of an inversion chamber 2 according to the invention of the first embodiment of a hyperpolarization device 100 according to the invention, part a) being a schematic view of the principle, part b) being a perspective cross-sectional view,

FIG. 3 shows a cross-sectional profile view of the first embodiment of the inversion chamber 2 according to the invention of the first embodiment of the hyperpolarization device 100 according to the invention,

FIG. 4 shows the profile of the magnetic inversion field 6 generated in the first inversion chamber design 2 of the first hyperpolarization device design 100 according to the invention, with the position in cm along the axis S of the portion 33 on the x-axis, and the value of the magnetic inversion field 6 (in mT) along the direction Z on the y-axis, where the axis S is parallel to the direction Z; The field 6 was measured using a teslameter and compared with the field predicted by the equations of an ideal solenoid; position 0 corresponds to the center of chamber 2 (middle of magnetic screen 5); for this figure, the electric current used in solenoids 11 and 12 to measure the field using a teslameter is higher than the current required for use of the invention for polarization transfer.

FIG. 5 shows a cross-sectional profile view of a second embodiment of an inversion chamber 2 according to the invention of a second embodiment of a hyperpolarization device 200 according to the invention, which are the preferred embodiments of chamber 2 and device 200 of the invention,

FIG. 6 shows internal details of the second embodiment of the inversion chamber 2 according to the invention of the second embodiment of the hyperpolarization device 200 according to the invention, in particular its current divider bridges 20 and their power supply,

FIG. 7 shows internal details of the second embodiment of the inversion chamber 2 according to the invention of the second embodiment of the hyperpolarization device 200 according to the invention, in particular one of the internal solenoids 11 or 12 and its current divider bridge 20 and resistors 23,

FIG. 8 shows a cross-sectional profile view of a third embodiment of the inversion chamber 2 according to the invention of the third embodiment of the hyperpolarization device 300 according to the invention,

FIG. 9 shows in its part a) a cross-sectional profile view of a fourth embodiment of the inversion chamber 2 according to the invention of the fourth type of hyperpolarization device 400 according to the invention, and in part b) a perspective view of its magnetization means 11 or 12,

FIG. 10 shows in its part a) a cross-sectional profile view of a fifth embodiment of inversion chamber 2 according to the invention of the fifth embodiment of hyperpolarization device 500 according to the invention, and in its part b) a front view (perpendicular to the plane of its part a)) of its magnetization means 11 or 12.

These embodiments are in no way limiting, and in particular, it is possible to consider variants of the invention that comprise only a selection of the features disclosed hereinafter in isolation from the other features disclosed (even if that selection is isolated within a phrase comprising other features), if this selection of features is sufficient to confer a technical benefit or to differentiate the invention with respect to the prior art. This selection comprises at least one preferably functional feature which lacks structural details, and/or only has a portion of the structural details if that portion is only sufficient to confer a technical benefit or to differentiate the invention with respect to the prior state of the art.

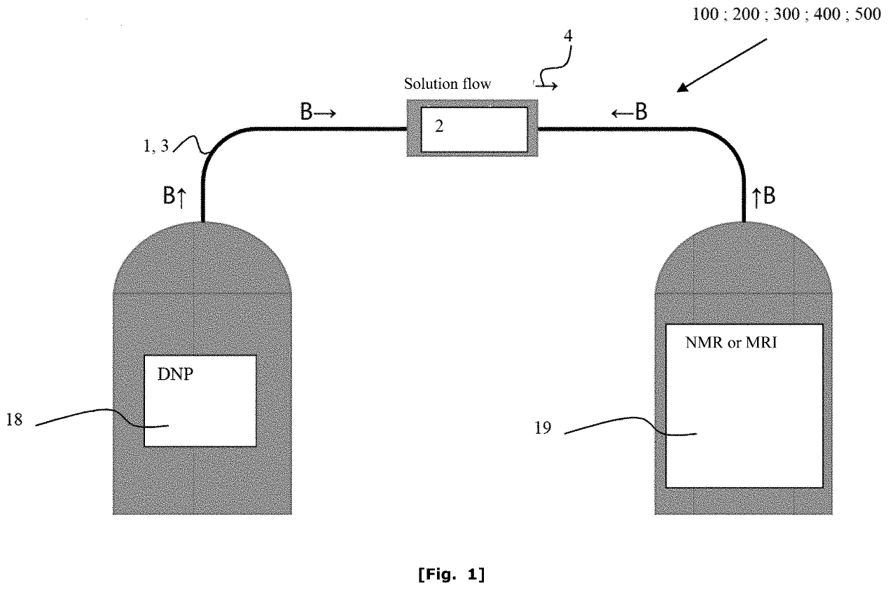

First, with reference to FIGS. 1 to 4, the first embodiment of a hyperpolarization device 100 according to the invention comprising the first embodiment of an inversion chamber 2 according to the invention will be described.

The device 100 comprises an inversion chamber 2, comprising:
an inlet arranged so that a flow of a solution 1 in the liquid state comprising:
a first type of nuclear spins that are hyperpolarized and with a first gyromagnetic ratio (preferably ¹H, which has the advantage of being hyperpolarized very rapidly upstream of the chamber 2 by DNP) and
a second type of nuclear spins with a second gyromagnetic ratio (preferably ¹³C, which has the advantage of a longer relaxation time than ¹H nuclear spins), the nuclear spins of both types being coupled by scalar spin-spin coupling in one or more molecules of the solution 1, enters the chamber 2 through this inlet;
an outlet arranged so that the solution flow 1 leaves the chamber 2 through this inlet, the inlet and outlet being arranged so that this solution 1 circulates as the solution flow within a conduit 3, a portion of which, called the inversion portion 33, passes through the inversion chamber 2.

The term “spin” or “nuclear spin” in the present description means a spin of an atomic nucleus (possibly within a molecule), carried by an atomic nucleus.

The chamber 2 further comprises a magnetic screen 5 surrounding the inversion portion 33 arranged to isolate the inversion portion 33 from ambient magnetic fields around the magnetic screen 5.

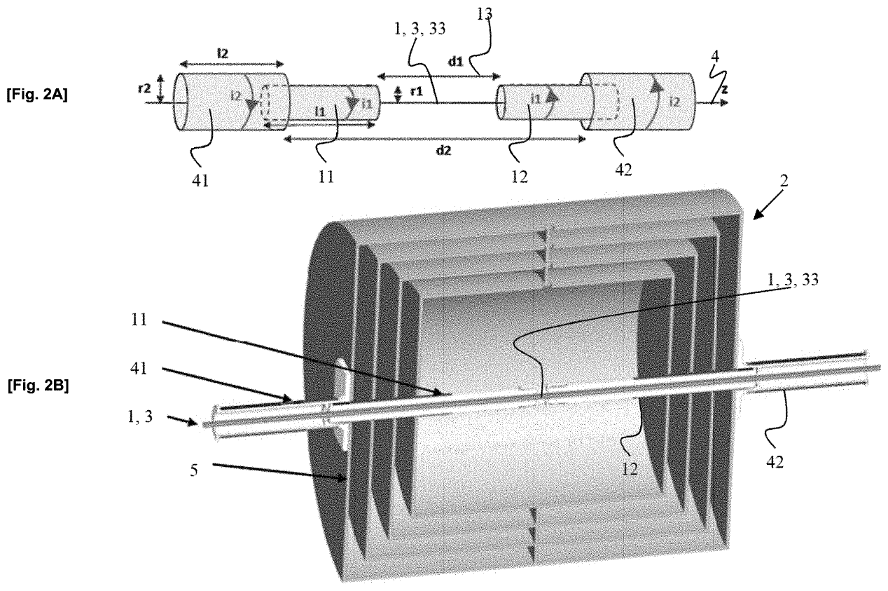

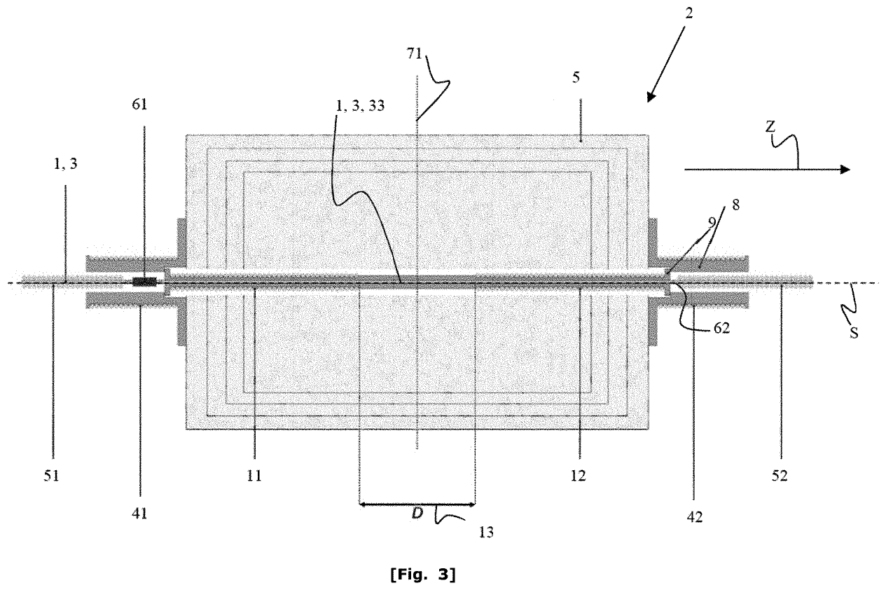

As shown in FIGS. 2a and 3, this screen 5 preferably comprises a plurality of layers (preferably concentric) for greater efficiency.

The inlet to the chamber 2 corresponds to the inlet of the conduit 3 into the screen 5 from outside the chamber 2.

The outlet from the chamber 2 corresponds to the outlet of the conduit 3 exiting the screen 5 from inside the chamber 2.

The chamber 2 further comprises at least one magnetization means 11, 12 located at least partially inside the magnetic screen 5, called at least one internal magnetization means 11, 12, and surrounding or framing or skirting at least part of the inversion portion 33. The at least one internal magnetization means 11, 12 is arranged to create, within the inversion portion 33, a magnetic inversion field 6 whose main component is along a direction Z and inverts (at an inversion plane 71) preferably once as it travels (along the axis S and direction Z) through the interior of the inversion portion 33 from the inlet to the outlet of the chamber 2, so as to transfer, within the inversion portion 33, the hyperpolarization from the first type of nuclear spins to the second type of nuclear spins during the flow of the solution 1 into the inversion portion 33 without immobilizing the solution 1 in the inversion portion 33, that is, with a non-zero velocity of solution 1 in the inversion portion 33 from the chamber inlet to the chamber outlet.

Inverting is used in this description to mean that the main component changes direction (while maintaining the same direction Z).

The notion of an inversion magnetic field 6 whose principal component is along a direction Z, is preferably understood in the present description as meaning that if the field 6 has a component transverse to the principal component, this transverse component always remains lower than:
10% of the principal component in the inverting direction Z, and/or
1 μT (e.g. if the scalar coupling is of the order of 100-200 Hz for a ¹H-¹³C pair), or even always lower than 0.1 μT (e.g. for a coupling of 10-20 Hz), the maximum transverse field allowing effective transfer decreasing linearly with the intensity of the scalar coupling between the nuclear spins at any point of solution 1 in the portion 33.

The chamber 2 is arranged so that the inversion magnetic field 6 has, in the inversion portion 33, preferably a single component which is solely in the direction Z (that is, with a component perpendicular to Z which is zero or negligible compared with the main component) and which inverts as it travels through the inversion portion 33.

The at least one internal magnetization means 11, 12 comprises:
on the inlet side of chamber 2, at least one internal inlet magnetization means 11,
on the outlet side of chamber 2, at least one internal outlet magnetization means 12.

In the present description, magnetization means preferably means an electromagnet, a permanent magnet, an assembly of electromagnets, an assembly of permanent magnets, or an assembly of electromagnet(s) and permanent magnet(s).

In the present description, a solenoid is taken to mean a conducting wire of an electromagnet, the wire being wound in multiple loops or turns and through which an electric current flows (or is arranged to flow).

In the present description, magnetic screen or shield 5 means a screen of any form (continuous (sheet, plate, etc.) and/or discontinuous (grid, lattice, etc.)), preferably metallic, and arranged to isolate the interior of the screen 5 from temporally continuous or low temporal frequency magnetic fields located around the screen 5, preferably:
arranged to decrease by at least a factor 10⁵, preferably at least 10⁶, the Tesla value of a temporally continuous magnetic field located around the screen 5 and having around the screen 5 a value less than or equal to 100 microtesla, and/or
with a screening factor of at least 10⁵, preferably at least 10⁶.

In the present description, solution 1 refers to a liquid or a mixture of liquids, which may optionally comprise suspended solid particles.

In this embodiment, the inversion portion 33 is straight and extends longitudinally along an axis S.

In this embodiment, the directions S and Z coincide.

In this embodiment, the at least one internal magnetization means 11, 12 comprises, at least partially within the magnetic screen 5, a pair of internal magnetization means 11, 12 at least partially surrounding or framing or skirting the inversion portion 33.

There is a gap 13 along the axis S (and direction Z) between:
the at least one internal inlet magnetization means 11, and
the at least one internal outlet magnetization means 12.

This allows, in this embodiment 100, the solution flow 1 is faster (the field profile 6 is closer to the ideal, so a higher flow speed can be chosen while maintaining efficient transfer).

More precisely, each internal magnetization means 11 and 12 comprises:
a part inside the screen 5 and surrounding or framing or skirting part of the inversion portion 33, and
a part outside the screen 5 (but inside one of the external magnetization means 41, 42 to be described later) and surrounding or framing or skirting another part of the inversion portion 33.

The inversion portion 33 corresponds to a portion of the conduit 3 surrounded or framed or skirted by the at least one internal magnetization means 11, 12.

Each internal magnetization means comprises an internal solenoid, the at least one internal magnetization means 11, 12 thus comprising, at least partially inside the magnetic screen 5, a pair of antiparallel internal solenoids 11, 12 whose turns are centered on the same axis S.

The chamber 2 further comprises at least one power supply (not shown, and preferably located outside the screen 5), preferably a single common power supply, arranged to electrically supply the two internal solenoids 11, 12 with currents i₁ (preferably of equal intensity) of opposite directions of rotation so that the leakage fields of the two internal solenoids 11, 12 oppose each other. This current i₁ is constant over time.

The advantage of a common power supply is greater simplicity, and a more stable inversion field 6.

Each internal magnetization means 11 or 12 respectively (that is, each solenoid 11 or 12 respectively) is arranged to produce a magnetic field that is constant over time.

Each internal magnetization means 11 or 12 respectively (that is, each solenoid 11 or 12 respectively) is arranged to produce a magnetic field opposite to the field of the other internal magnetization means 12 or 11 respectively (that is, of the other solenoid 12 or 11 respectively), so that the sum of the fields of these two internal magnetization means (that is, of those two solenoids 11, 12) inverts within (in an inversion plane 71 perpendicular to portion 33) the inversion portion 33, preferably in the center, along the direction S, of the inversion portion 33 and the gap 13.

The chamber 2 further comprises:
a magnetization means, known as the external inlet magnetization means 41, at least partially outside the magnetic screen 5 and extending at least as far as the inlet to the inversion chamber 2; the external inlet magnetization means 41 may be both outside and inside the screen 5, but is preferably only outside the screen 5, and
a magnetization means, known as the external outlet magnetization means 42, at least partially outside the magnetic screen 5 and extending at least as far as the outlet to the inversion chamber 2; the external outlet magnetization means 42 may be both outside and inside the screen 5, but is preferably only outside the screen 5.

Each external magnetization means 41 or 42 is arranged to maintain within the conduit 3 an input magnetic field (constant over time) at the inlet to the inversion chamber 2 and an output magnetic field (constant over time) at the outlet from the inversion chamber 2.

Both the input magnetic field and the output magnetic field are typically at least 4 mT in the direction Z, which is its main direction.

Both the input magnetic field and the output magnetic field ensure that polarization is not lost due to the rotation of the non-adiabatic field (due, for example, to the combined effect of the ambient field and the magnetic screen 5).

Each external magnetization means 41, 42 surrounds or frames or skirts at least part of the at least one internal magnetization means 11, 12 inside or outside the screen 5, preferably at least outside the screen 5, preferably only outside the screen 5.

The external inlet magnetization means 41 surrounds or frames or skirts a portion, located outside the screen, of the solenoid 11.

The external outlet magnetization means 42 surrounds or frames or skirts a portion, located outside the screen, of the solenoid 12.

The device 100 further comprises:
an upstream magnetization means or solenoid 51 which surrounds the conduit 3 continuously between:
a zone which is both outside the magnetic screen 5 and outside the external inlet magnetization means 41, and
a zone which is both outside the magnetic screen 5 and inside the external inlet magnetization means 41, and
a downstream magnetization means or solenoid 52 which surrounds the conduit 3 continuously between:
a zone which is both outside the magnetic screen 5 and outside the external outlet magnetization means 42, and
a zone which is both outside the magnetic screen 5 and inside the external outlet magnetization means 42.

Each magnetization means 51 or 52 is designed to maintain a magnetic field (constant over time) in the conduit 3 upstream and downstream of the chamber 2 respectively.

Each external magnetization means, inlet 41 or outlet 42 respectively, surrounds or frames or skirts a junction zone 61 at the inlet to the chamber 2 or 62 at the outlet from the chamber 2 outlet between:
a part of the conduit 3 penetrating the external magnetization means, respectively inlet 41 or outlet 42, while being surrounded or framed or skirted by the magnetization means, respectively upstream 51 or downstream 52, and
a part of the conduit 3 surrounded or framed or skirted by the at least one internal magnetization means 11, 12 and preferably penetrating the magnetic screen 5 through the inlet or outlet of the inversion chamber 2 respectively.

Each external magnetization means comprises or is an external solenoid, the chamber 2 thus comprising, at least partially outside the magnetic screen 5, a pair of antiparallel external solenoids 41, 42 whose turns are preferably centered on the same axis S.

The chamber 2 further comprises at least one power supply (not shown, and preferably located outside the screen 5), preferably a common power supply, arranged to electrically supply the two external solenoids 41, 42 with currents i₂ (preferably of equal intensity) of opposite directions of rotation. This current i₂ is constant over time.

The current i₁ in the solenoid 11 rotates in the same direction as the current i₂ in the solenoid 41.

The current i₁ in the solenoid 12 rotates in the same direction as the current i₂ in the solenoid 42.

The advantage of a common power supply is greater simplicity, and a more stable inversion field 6.

Each external solenoid 41 or 42 is carried around the conduit 3, surrounding the conduit 3, via an external support piece 8 which:
on the side of the conduit 3, is not in contact with the conduit (but surrounds only part of the upstream solenoid 51 or downstream solenoid 52, only part of at least one internal solenoid 11, 12, and the junction zone 61 or 62), and
on the side of each external solenoid 41 or 42, comprises reliefs (wound in the form of turns around the external support piece 8) arranged to accommodate and position the turns of the external solenoid 41 or 42.

As previously described, the at least one internal magnetization means 11, 12 comprises at least one internal solenoid 11, 12.

Each internal solenoid 11, 12 can be carried at least in part by the inversion portion 33, at least partially surrounding the inversion portion 33, via an internal support piece 9 which:
on the conduit 3 side, is in contact with the conduit 3, and
on the side of each internal solenoid 11, 12, comprises reliefs (wound in the form of turns around the internal support piece 9) arranged to accommodate and position the turns of the internal solenoid 11 or 12 along the conduit 3 and in particular along the inversion portion 33.

The inversion portion 33 and/or conduit 3 is a capillary whose largest dimension, perpendicular to the solution flow 1 (that is, perpendicular to the axis S), is less than 5 mm. This allows better control of the field 6, as the further away from the center of the portion 33 (in a cross-sectional plane perpendicular to the portion 33), the greater the transverse component of the field 6 is likely to be.

The chamber 2 is arranged so that, in the inversion portion 33, the inversion magnetic field 6 is comprised, in absolute value along the direction Z, at least between 0 mT and 0.1 mT, or even at least between 0 mT and 0.2 mT. The field strength 6 in the portion 33 preferably has at least one value greater than 10 times the ratio (coupling J of the two types of spins)/(difference in the gyromagnetic ratios of the two types of spins).

The chamber is arranged so that, in the inversion portion 33, the inversion magnetic field 6 reverses at least between a value +Bₘₐₓ along the direction Z and a value in the opposite direction +Bₘₐₓ along the direction Z, with Bₘₐₓ being equal to at least 0.1 mT, or at least 0.2 mT.

As part of a method for using device 100, the first type of nuclear spins preferably has a higher gyromagnetic ratio than the second type of nuclear spins.

In addition to the chamber 2 just described, the hyperpolarization device 100 comprises a device 18 arranged to supply solution 1 to the inlet (that is, upstream) of the inversion chamber 2 via conduit 3.

The device 18 comprises:
preferably a dynamic nuclear polarization (DNP) device 18, preferably a dissolution dynamic nuclear polarization (dDNP) device, connected to the conduit 3, and/or
any other device 18 capable of producing and/or supplying a solution comprising both types of nuclear spin.

The device 100 further comprises a nuclear magnetic resonance (NMR) spectrometer 19 or magnetic resonance imaging (MRI) device 19 connected to the outlet (that is, downstream) of the inversion chamber 2 via the conduit 3.

The device 100 further comprises, downstream of the chamber 2, that is, between the chamber 2 and the device 19, means (not shown) for purifying the solution 1, e.g. one or more polarizing matrices, e.g. HYPOP polarizing matrices for purifying the solution 1 by removing traces of polarizing agent.

The transfer of polarization from one nucleus to the other is complete if it is adiabatic, in other words, if it is sufficiently slow. The minimum time for an adiabatic transition Tₜᵣₐₙₛ can be calculated by Landau-Zener theory in the simple case of a linear variation of magnetic field strength 6 over time for two coupled spins (first type and second type of nuclear spins of different gyromagnetic ratios coupled by scalar coupling, preferably coupled within the same molecule) moving in the portion 33 (the field 6 being constant over time at each fixed point within the portion 33) which can be written as

$${B}_{z} ( t ) = {B}_{max} ( 1 - 2 \frac{t}{{τ}_{trans}} ) , \qquad [ Math . 1 ]$$

where field 6 is +Bₘₐₓ at time t=0 (typically at the inlet to the chamber 2) and −Bₘₐₓ at time t=Tₜᵣₐₙₛ (typically at the outlet of the chamber 2). The value of the Bₘₐₓ field is given by the condition

$${B}_{max} ≫ \frac{{J}_{IS}}{{γ}_{I} - {γ}_{S}} , \qquad [ Math . 2 ]$$

where J_{IS}, Y_{I} and t Y_{S} are the scalar coupling between spins in Hz and their gyromagnetic ratio in Hz. T⁻¹. To obtain a numerical value for this condition, we can choose

$${B}_{max} \approx 10 \frac{{J}_{IS}}{{γ}_{I} - {γ}_{S}} , \qquad [ Math . 3 ]$$

which ranges from 0.3 to 63 μT for a pair of ¹H and ¹³C spins with typical couplings (between 1 and 200 Hz, respectively). Landau-Zener theory shows that the minimum transfer time for an adiabatic transition in the linear magnetic field profile from +Bₘₐₓ to −Bₘₐₓ (see equation Math.1) is given by the condition

$${τ}_{trans} ≫ \frac{1}{{J}_{IS}} . \qquad [ Math . 4 ]$$

To obtain a numerical value for this condition, we can choose

$${τ}_{trans} \approx 10 \frac{1}{{J}_{IS}} , \qquad [ Math . 5 ]$$

which ranges from 0.05 to 10 s for a pair of ¹H and ¹³C spins with typical couplings (between 1 and 200 Hz, respectively).

It should be noted that transfer can be considerably reduced if a non-linear field profile is adopted. The constant adiabaticity profile (that is, that which allows the fastest possible adiabatic transfer) can be calculated numerically. A pair of solenoids 11, 12 aligned along the same axis S, with opposing leakage fields, enable this ideal profile to be approached with a distance between the solenoids (distance D referenced 13 in FIG. 3). This distance 13 and the current flowing through the solenoids 11, 12 can be influenced.

In this way, it is possible to easily calculate and optimize the flow velocity of solution 1 in portion 33 and therefore its dwell time in portion 33 based on the field 6 and on the two types of spins and their coupling.

The profile of the field 6 experienced by a pair of coupled nuclear spins in the solution 1 as a function of time depends on:
the profile, in space (and constant in time), of the field 6, which depends on the arrangement of the various internal inlet 11 and outlet 12 magnetization means, and possibly on the current flowing through them if they are not permanent magnets. The field profile 6 along the position S can be calculated using conventional ideal solenoid equations, and optimized by optimizing the current i₁.
the speed of the solution flow 1, which can be calculated and optimized as previously explained and simply adjusted by a pump or valve or any other known means of adjusting the speed of the solution flow 1.

Thus, to summarize this embodiment of the invention:
The magnetic screen 5 screens the earth's magnetic field and those produced by the devices around chamber 2,
The internal magnetization means 11, 12 create the spatial inversion of the field 6,
The external magnetization means 41, 42 serve to maintain a sufficient field at the inlet and outlet of the inversion chamber 2,
The conduit 3 (which is a capillary) is itself surrounded by a coil or magnetization means 51, 52 (wound and glued onto the conduit 3) to sustain a sufficient magnetic field throughout the transfer of the solution from the device 18 to the chamber 2 and then from the chamber 2 to its destination 19.

Typically, the device or method according to the invention uses dDNP to polarize the first spin type ¹H and then this polarization is transferred to the 2^{nd} spin type ¹³C in the liquid state. In the case of the invention, inversion is achieved by moving the solution 1 through a field profile 6 in space. In addition, the invention makes highly preferential use of DNP or dDNP to prepare the hyperpolarized ¹H solution 1 upstream of the chamber 2.

The device or method according to the invention enables hyperpolarized ¹³C metabolite solutions to be produced in less than 20 min, without the need for complex instrumentation, as the production of a solution containing ¹H nuclei hyperpolarized by DNP is faster and simpler than direct ¹³C production (e.g. by cross-polarization), and the transfer of the polarization from ¹H to ¹³C (or ¹⁵N or ³¹P) into chamber 2 in a continuous flow is very fast, simple, and uninterrupted. Unlike cross-polarization, adding an inversion chamber 2 according to the invention does not require any major modification of the polarizer, but only the addition of inexpensive equipment at the polarizer outlet.

Typically, hyperpolarized ¹³C solutions are produced rapidly (<20 min) for molecules where the ¹³C nucleus is coupled to at least one ¹H nucleus. The invention uses a common protocol to produce a solution 1 whose ¹H is hyperpolarized by “dissolution dynamic nuclear polarization” (dDNP). Polarization is then transferred from ¹H to ¹³C in the solution 1 in the liquid state by transporting solution 1 through a magnetic field profile 6 that inverts in a controlled manner. This field profile 6 is obtained by using the magnetic screen 5, which cancels out ambient fields (the residual field is on the order of nT) provided with a pair of antiparallel constant-current solenoid coils 11, 12, or more generally a pair of internal inlet 11 and outlet 12 magnetization means, or at least one internal magnetization means 11, 12. Each coil 11, 12 produces a constant, opposing magnetic field 6. The capillary 3, 33 passes through the solenoids 11, 12 and the magnetic screen 5, so that when the solution 1 is pushed into the capillary 3, 33, the molecules experience a inversion of the magnetic field 6 over time. Scalar coupling (J-coupling) between the nuclei of ¹H and ¹³C enables polarization transfer. The theory of this transfer is well established, and enables us to optimize the field profile for the molecule to be hyperpolarized. This “in-flow” transfer, meaning that the solution 1 is not immobilized, enables rapid transfer and minimizes losses due to relaxation.

In this way, the invention enables nuclear spins with low gyromagnetic ratios (e.g. ¹³C) to be polarized for MRI applications more quickly or with less complex instrumentation than existing methods.

An experiment was carried out using the device shown in FIG. 3 to polarize nuclear spins of ¹³C-formate and ¹³C-pyruvate. A sharp increase in the polarization of these molecules was observed, with a final polarization of several percent measured by liquid magnetic resonance.

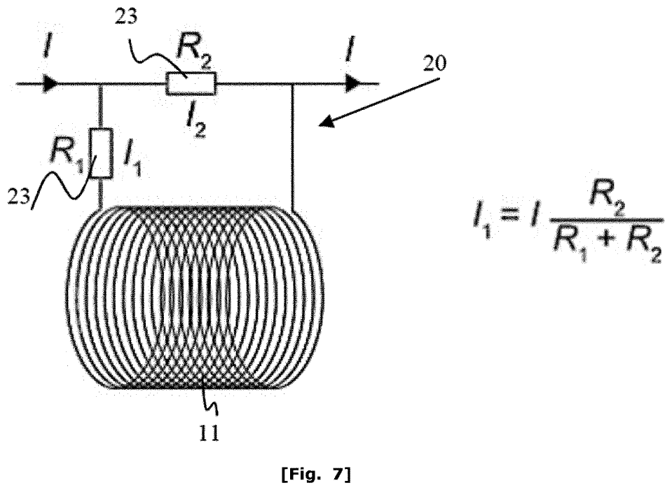

With reference to FIGS. 1 and 5 to 7, the second embodiment of the hyperpolarization device 200 according to the invention comprising the second embodiment of the inversion chamber 2 according to the invention will now be described, and these embodiments will be described only for their differences from the first embodiments of the chamber 2 and device 100 previously described.

The device 200 is more precise than the device 100.

In this embodiment, the at least one internal magnetization means 11, 12 comprises, at least partially within the magnetic screen 5, multiple of internal solenoids 11, 12, at least partially surrounding the inversion portion 33 and electrically interconnected by current divider bridges 20.

The internal solenoids 11, 12 are separated into two assemblies 110, 120 of internal solenoids:
a first assembly 110 of internal inlet solenoids 11 all on the inlet side of the chamber 2,
a second assembly 120 of internal outlet solenoids 12 all on the outlet side of the chamber 2.

Each pair of neighboring internal solenoids 11 (of the assembly 110) is electrically connected by a current-dividing bridge 20 (and only by this bridge 20), preferably with no intermediate space between these internal solenoids 11, but with no direct electrical contact between these neighboring solenoids 11 (that is, a turn of one solenoid 11 does not continue into a turn of another neighboring solenoid 11).

Each pair of neighboring internal solenoids 12 (of the assembly 120) is electrically connected by a current-dividing bridge 20 (and only by this bridge 20), preferably with no intermediate space between these internal solenoids 12, but with no direct electrical contact between these neighboring solenoids 12 (that is, a turn of one solenoid 12 does not continue into a turn of another neighboring solenoid 12).

The first assembly 110 is electrically connected to the second assembly 120 are connected to the same source 21, but with a direction of electric current rotation of each solenoid 11 of the assembly 110 which is opposite to the direction of electric current rotation of each solenoid 12 of the assembly 120.

The assembly 110 comprises as many solenoids 11 as the assembly 120 comprises solenoids 12.

The chamber 2 further comprises at least one power supply, preferably a common power supply, arranged to electrically supply the two assemblies 110, 120 of internal solenoids with currents i₁ (preferably of the same intensity) of opposite directions of rotation so that the leakage fields of the two assemblies 110, 120 of internal solenoids oppose each other, it is constant over time.

The advantage of a common power supply is greater simplicity, and a more stable inversion field 6.

The two assemblies 110 and 120 are antiparallel.

The turns of solenoids 11 and 12 are centered on the same axis S

The chamber does not comprise a gap between the two assemblies 110, 120 of internal solenoids 11, 12, that is, the first assembly 110 is flush with the second assembly 120, with only a gap of simple mechanical clearance possibly remaining.

In this embodiment 200, this enables faster transfer and minimizes relaxation losses during transfer.

Each bridge 20 comprises a pair of resistors 23.

The current divider bridges 20 comprise resistors 23 which can be varied via an adjustment interface, said adjustment interface being arranged to vary the resistors 23 of the divider bridges 20 via this interface so as to adjust or optimize the magnetic field inversion profile 6.

As adjustable resistors 23 and adjustment interface, any type of variable resistor technology can be used, for example using any type of potentiometer or rheostat controlled from outside the display 5 by analog and/or digital means, a touch screen, etc.

The spatial profile of the field 6 can be refined by adjusting:
the current it in each solenoid 11 and/or 12, and/or
the values (equal or different) of the various resistors 23.

Even without adjusting the resistors 23, the device 200 is more precise than the device 100.

All the resistors 23 of all the bridges 20 are mounted on a single printed circuit board which is, for example, integrated inside the screen 5.

The external inlet magnetization means 41 surrounds or frames or skirts a portion, located outside the screen, of the assembly 110.

The external outlet magnetization means 42 surrounds or frames or skirts a portion, located outside the screen, of the assembly 120.

The chamber 2 of the device 200 therefore corresponds to the chamber 2 of the device 100 wherein:
the solenoid 11 of the device 100 is replaced by the assembly 110 and its bridges 20 of device 200
the solenoid 12 of the device 100 is replaced by the assembly 120 and its bridges 20 of device 200.

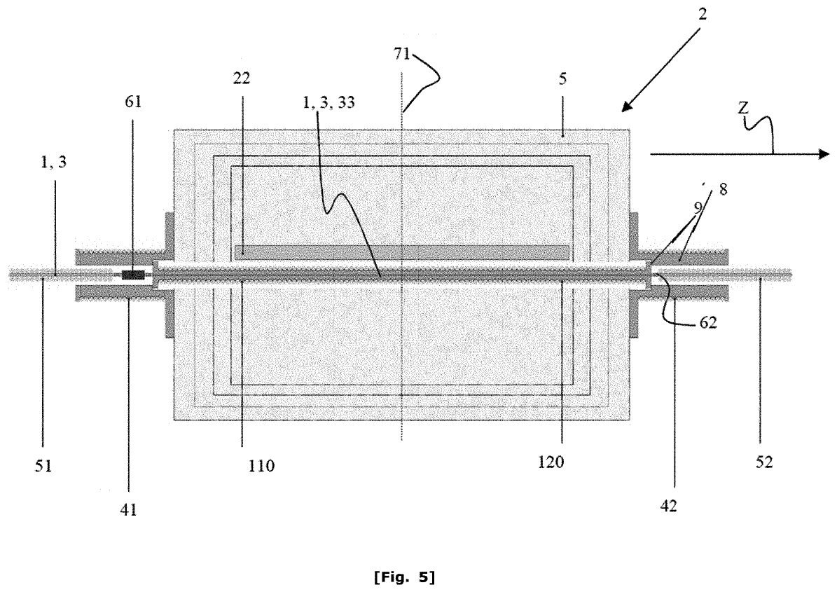

In a variant of the embodiment shown in FIGS. 5 to 7:
the portion 33 is V-shaped, the inversion of the field 6 occurring at the tip of the V, the tip of the V delimiting the separation between the two assemblies 110 and 120, and/or
there is a separation between the assemblies 110 and 120, although this is less favorable.

The two embodiments described in FIGS. 1 to 7 can be generalized by replacing the term “solenoid” by “magnetization means” (or “electromagnet”, “permanent magnet”, “assembly of electromagnets”, “assembly of permanent magnets”, or “assembly of electromagnet(s) and permanent magnet(s)”). In the case of permanent magnet(s), the means of supplying electrical power to the solenoids as described above are no longer required.

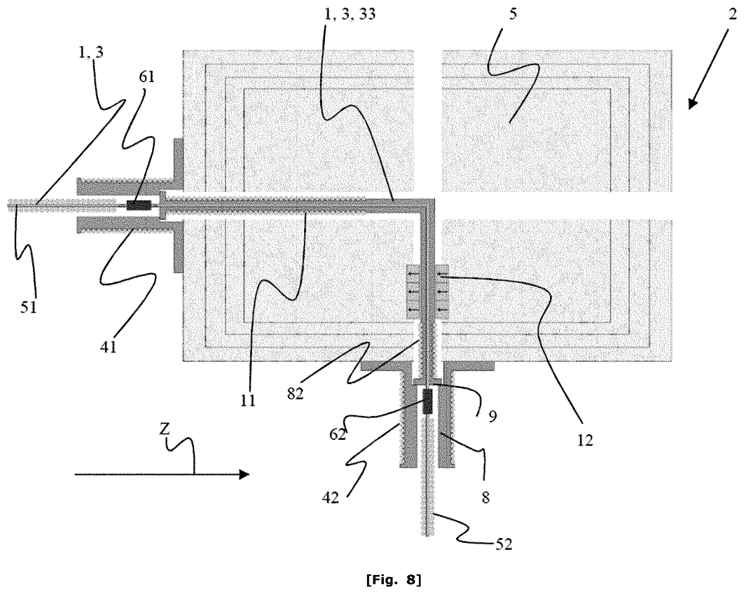

With reference to FIGS. 1 and 8, the third embodiment of the hyperpolarization device 300 according to the invention comprising the third embodiment of the inversion chamber 2 according to the invention will now be described, and these embodiments will be described only for their differences from the first embodiments of the chamber 2 and the device 100 previously described.

In this embodiment, the inversion portion 33 is not straight.

In this embodiment, a first and a second part of the inversion portion 33 form a right angle, but can generally form any angle.

The internal inlet magnetization means 11 comprises or is an internal inlet solenoid 11 surrounding part of the first part of the portion 33.

The means 11 create, in the first part of the portion 33, a magnetic field that is parallel to Z and to the direction of elongation of the first part of the portion 33.

The chamber 2 comprises means for powering the solenoid 11 with direct current.

The internal outlet magnetization means 12 comprises or is a group 12 of permanent magnet(s) and/or Helmholtz coil(s) surrounding part of the second part of the portion 33, and arranged to emit a magnetic field perpendicular to the part of the portion 33 they surround.

The means 12 create, in the second part of the portion 33, a magnetic field that is parallel to Z and perpendicular to the direction of elongation of the second part of the portion 33.

As a result, the magnetic field 6 inverts in the direction Z as the solution flow 1 passes through the portion 33.

Note that in an unshown variant of FIG. 8, there is:
the non-straight portion 33
The internal inlet magnetization means 11 comprises or is a group 11 of permanent magnet(s) and/or Helmholtz coil(s) surrounding part of the first part of the portion 33, and arranged to emit, in the first part of the portion 33, a magnetic field perpendicular to the part of the portion 33 they surround,
The internal outlet magnetization means 12 which comprises or is an internal outlet solenoid 12 surrounding part of the second part of the portion 33 and creating, in the 2^{nd} part of the portion 33, a magnetic field parallel to Z and to the direction of elongation of the second part of the portion 33.

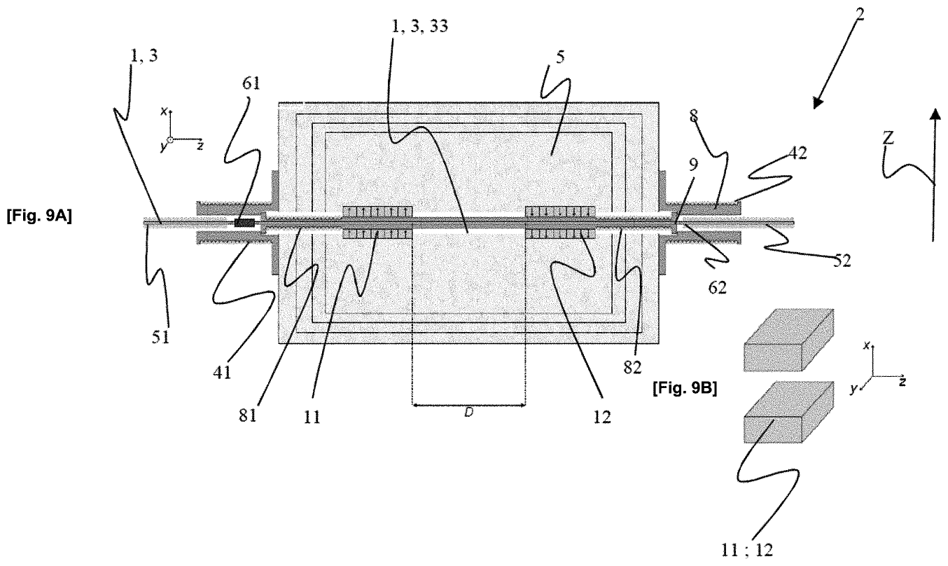

With reference to FIGS. 1 and 9, the fourth embodiment of the hyperpolarization device 400 according to the invention comprising the fourth embodiment of the inversion chamber 2 according to the invention will now be described, and these embodiments will be described only for their differences from the third embodiments of the chamber 2 and the device 300 previously described.

With reference to FIG. 9, we therefore note that in a variant of FIG. 8, there is:
the straight portion 33
The internal inlet magnetization means 11 comprises or is a group 11 of permanent magnet(s) and/or Helmholtz coil(s) surrounding part of the first part of the portion 33, and arranged to emit, in the portion 33, a magnetic field perpendicular to the part of the portion 33 they surround,
The internal inlet magnetization means 12 which comprises or is a group 12 of permanent magnet(s) and/or Helmholtz coil(s) surrounding part of the second part of the portion 33, and arranged to emit, in the portion 33, a magnetic field perpendicular to the part of the portion 33 they surround, but in the direction opposite the field of the means 11.

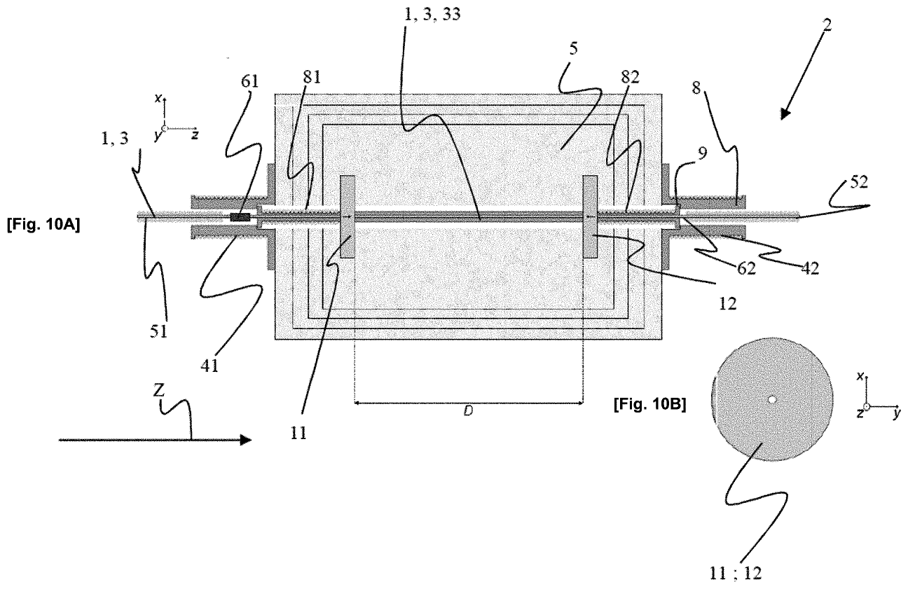

Furthermore, it should be noted that, for FIGS. 8 to 10:
the device according to the invention comprises an intermediate inlet magnetization means 81 between the inlet of the chamber 2 and the (or at least one) internal magnetization means 11 (in the case of FIG. 9, FIG. 10, and the variant of FIG. 8 for which the means 11 and 12 would be interchanged), and/or
the device according to the invention comprises an intermediate outlet magnetization means 82 between the outlet of the chamber 2 and the (or at least one) internal magnetization means 12 (in the case of FIG. 8, FIG. 9, and FIG. 10)

Each of the means 81 and 82 surrounds or frames or skirts at least part of the portion 33.

Each of the means 81 and 82 comprises a solenoid.

The intermediate magnetization means 81 is arranged to maintain in the conduit 3 an intermediate input magnetic field (constant over time), parallel to the direction of elongation of the conduit 3 through the inlet to the chamber 2, between the magnetic field of the means 41 in the conduit 3 and the magnetic field of the mean(s) 11 in the portion 33.

The intermediate magnetization means 82 is arranged to maintain in the conduit 3 an intermediate output magnetic field (constant over time), parallel to the direction of elongation of the conduit 3 through the outlet to the chamber 2, between the magnetic field of the means 42 in the conduit 3 and the magnetic field of the mean(s) 12 in the portion 33.

The function of the means 81 and 82 is to ensure that the orientation of the field felt by the spins is constant. Without them, the success of a polarization transfer method by the device according to the invention of FIGS. 8, 9 and 10 would risk depending too heavily on the orientation of the screen 5 in space and in relation to the ambient magnetic fields.

The orientation of the field, which changes by 90° in the course of space (and therefore time), is not a problem if the change is sufficiently slow (adiabatic). An example of an adiabatic condition would be

$$\frac{d α}{dt} ≪ γ B ( t ) \qquad [ Math . 6 ]$$

Where a is the angle of the field B(t) at time t and y is the lowest gyromagnetic ratio of the two spins. As a numerical expression, this results in:

$$10 \frac{d α}{dt} < γ B ( t ) \qquad [ Math . 7 ]$$

It should be noted that none of the embodiments of the device according to the invention or of the chamber according to the invention just described with reference to FIGS. 1 to 10 comprises means for emitting microwaves (that is, electromagnetic radiation of frequency greater than 1 GHz or between 1 GHz and 300 GHz) into the chamber and/or into the portion 2.

With reference to FIGS. 1 and 10, the fifth embodiment of the hyperpolarization device 500 according to the invention comprising the fifth embodiment of the inversion chamber 2 according to the invention will now be described, and these embodiments will be described only for their differences from the first embodiments of the chamber 2 and the device 100 previously described.

With reference to FIG. 10, note that there may therefore be:
the straight portion 33
The internal inlet magnetization means 11 comprises or is a group 11 of permanent magnet(s) and/or Helmholtz coil(s) surrounding or skirting part of the first part of the portion 33, and arranged to emit a magnetic field parallel to the part of the conduit 33 they surround,
The internal outlet magnetization means 12 comprises or is a group 12 of permanent magnet(s) and/or Helmholtz coil(s) surrounding or skirting part of the second part of the portion 33, and arranged to emit a magnetic field parallel to the part of the conduit 33 they surround.

With reference to FIGS. 1 to 10, we will now describe the various embodiments of the method according to the invention, implemented in the various embodiments of hyperpolarization devices 100, 200, 300, 400, 500 according to the invention.

In all devices 100, 200, 300, 400 and 500, the hyperpolarization method comprises supplying the solution 1 in a liquid state, said solution 1 comprising:
the first type of nuclear spins (e.g. ¹H hydrogen nuclei) with a first gyromagnetic ratio and hyperpolarized and
the second type of nuclear spins (e.g. carbon ¹³C, nitrogen ¹⁵N, or phosphorus ³¹P nuclei) having a second gyromagnetic ratio and not being hyperpolarized;
the nuclear spins of the two types being, in one or more molecules of solution 1, coupled by a scalar spin-spin coupling also referred to by the person skilled in the art as “J-coupling”. This coupling is a persistent coupling (without chemical exchange).

The solution 1 is supplied to the inversion chamber 2 so that this solution 1 circulates as the solution flow 1 within the conduit 3, a portion of which, called the inversion portion 33, passes through the inversion chamber 2.

The inversion chamber 2 comprises an inlet through which the solution flow 1 enters and an outlet through which the solution flow exits 1.

The inversion chamber 2 comprises the magnetic screen 5 which surrounds the inversion portion 33 and isolates the inversion portion 33 from ambient magnetic fields around the magnetic screen 5.

In devices 100, 200, 300, 400 and 500, the method according to the invention further comprises the creation in the portion 33, by the at least one magnetization means located at least partially inside the magnetic screen 5, of called at least one internal magnetization means 11, 12, and surrounding or framing or skirting at least part of the inversion portion 33, of the inversion magnetic field 6 whose main component is along the direction Z and inverts, preferably once, traveling through the interior of the inversion portion 33 so as to transfer, within the inversion portion 33, the hyperpolarization from the first type of nuclear spins to the second type of nuclear spins during the flow of solution 1 with non-zero velocity of the solution 1 in the inversion portion 33 from the inlet to the chamber 2 to the outlet from the chamber 2, that is, without immobilizing the solution 1 in the inversion portion 33. This is an “avoided crossing” transfer, the probability of which can be calculated using Landau-Zener theory.

As seen previously, the inversion portion 33 may or may not be straight.

The main component of the inversion field 6, in the direction Z, may be perpendicular or parallel (or even oblique in some variants) to the direction in which the solution 1 flows in the portion 33. The direction Z is constant, but the direction of solution flow 1 in the portion 33 can change, for example through bends, curves, or turns in the portion 33.

In the case of the device 100 or 500:
each internal magnetization means 11, 12 produces a magnetic field that is constant over time and is opposite to the field of the other internal magnetization means, the sum of the fields of these two internal magnetization means inverting within 71, preferably at the center of, the inversion portion 33,
the two internal magnetization means 11, 12 are fed by currents i₁ in opposite directions of rotation, and their leakage fields oppose each other.

The preferred solution, in order to achieve an ideal field profile 6, is to use internal magnetization means 11 and 12 (or 110 and 120) that are symmetrical (with respect to a plane 71 perpendicular to the portion 33, which is preferably rectilinear) and face each other inside the screen 5 and around or along the portion 33, as is the case for the devices 100, 200 and 500.

In the case of the device 200:
the two assemblies (110, 120) of internal solenoids are supplied with currents i₁ in opposite directions of rotation, and their leakage fields oppose each other,
the method optionally comprises varying the resistors 23 of the dividing bridges 20 via the adjustment interface, so as to adjust or optimize the magnetic field inversion profile 6.

In the case of devices 100, 200, 300, 400 and 500:
supplying the solution 1 to the inversion chamber 2 comprises:
preferably supplying solution 1 from the dynamic nuclear polarization device (18) DNP, preferably dDNP, connected to the conduit 3, and/or
supplying the solution 1 from any other device 18 capable of producing and/or supplying a solution comprising both types of nuclear spin,
the inlet 41 or outlet 42 external magnetization means maintain in the conduit 3 respectively the input magnetic field at the inlet of the inversion chamber 2 or the output magnetic field at the outlet of the inversion chamber 2,
the two external magnetization means 41, 42 are supplied with currents i2 in opposite directions of rotation,
the method preferably comprises purifying the solution 1 by purification means, e.g. one or more polarizing matrices, downstream of the chamber 2, that is, between the chamber 2 and the device 19,
the method further comprises supplying the solution 1, after passing through the inversion chamber 2, to the nuclear magnetic resonance (NMR) spectrometer 19 or the magnetic resonance imaging (MRI) device 19 via the conduit 3.

The method may, for example, comprise ¹³C hyperpolarization of metabolites for MRI detection of prostate cancer, or ¹³C hyperpolarization of metabolites (or other low-gyromagnetic-ratio nuclei coupled to ¹H nuclei) for nuclear magnetic resonance (NMR) drug screening, NMR chemical or biological kinetics and metabolomics studies, protein/ligand interaction for drug screening, etc.

For example, a transfer was carried out under the following experimental conditions:
hyperpolarization device used: device 100
conduit 3 upstream and downstream of chamber 2: a teflon capillary with an external diameter of 3.2 mm and an internal diameter of 1.6 mm (circular cross-section), around which a 0.5 mm copper wire (solenoid 51 or 52) was wound and bonded. A current of 2 A supplied by a laboratory power supply passed through copper wire (solenoid 51 or 52), producing a magnetic field on the order of 4 mT in the capillary upstream and downstream of chamber 2.
composition of the solution 1 at the inlet to chamber 2: a DNP sample of 100 μL (composition: 0.43 M sodium ¹³C-formate, 0.44 M sodium [3-¹³C]-pyruvate, 0.44 M sodium [2-¹³C]-pyruvate, 0.45 M sodium [1-¹³C]-pyruvate and 50 mM TEMPOL dissolved in 1:3:6 H₂O: D₂O: D₈-glycerol v/v/v) whose ¹H spins were hyperpolarized in an 18 dDNP polarizer at 1.2 K and 7.05 T. The ¹H polarization of the sample before dissolution was ≈50%. The weak ¹³C polarization of the sample (acquired while the ¹H spins were being polarized) was reduced to 0% by a series of radiofrequency pulses before dissolution (to ensure that the ¹³C polarization in liquid after dissolution and transfer came exclusively from the transfer from the ¹H). The sample was dissolved in 5 mL D₂O pressurized to 6 bar and heated to 9 bar and 175° C., then transferred using a rapid transfer and injection system (see, for example, “An automated system for fast transfer and injection of hyperpolarized solutions” by Ceillier et al, Journal of Magnetic Resonance Open Volumes 8-9, December 2021, 100017) in 1.8 s to an NMR tube placed in a benchtop NMR spectrometer operating at 1.88 Tesla (referenced 19 in FIG. 1). The velocity of the solution during transfer was ≈5 m.s⁻¹. The conduit for transferring the solution from the polarizer to the benchtop spectrometer passed through the inversion chamber, which was positioned as close as possible to the outlet of the dDNP polarizer (to minimize ¹H polarization losses).
all solenoids 11, 12 are made of copper wire, wire diameter 0.5 mm, coil diameter 12 mm, 112 coils, solenoid length 7.3 cm, spaced 10.4 cm apart and supplied with a current i₁ of 0.05 amperes
all solenoids 41, 42 are made of copper wire, wire diameter 0.5 mm, coil diameter 1.8 cm, 107 coils, solenoid length 70 cm and supplied with a current i₂ of 1 ampere
all solenoids 51, 52 are made of copper wire, wire diameter 0.5 mm, coil diameter 3.2 mm, >2000 coils, solenoid length >100 cm and supplied with a current of 2 amperes
the support 8 is made of 3D-printed resin (clear resin) comprising a groove for positioning the copper wire as precisely as possible,
the support 9 is made of 3D-printed resin (clear resin) comprising a groove for positioning the copper wire as precisely as possible,
the conduit 3, 33 is made from a 3D-printed substrate with a square hole (4 mm on each side) through which the capillary (or conduit) 3,33 with an external diameter of 3.2 mm (circular cross-section) and an internal diameter of 1.6 mm (circular cross-section) passes,
the screen 5 is made of μ-metal, comprises 4 concentric layers of approx. 1mm thickness, and has a length, along the axis S, of 32.6 cm (MS-IL, Twinleaf)
the distance D, 13 is 7.3 cm.

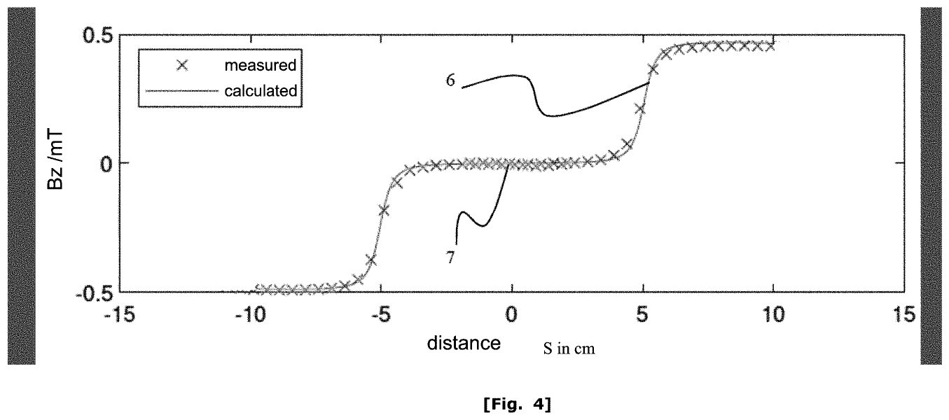

The resulting field is shown in FIG. 4.

The ¹³C polarizations obtained in the liquid state at the end of this experiment for the four molecules present in the solution are shown in the table below. The experiment was repeated twice (“Inversion #1”, “Inversion #2”). In addition, two control experiments were carried out:
In the “No inversion #1” experiment, the solution passed through the inversion chamber, but the coils had been connected in such a way that the magnetic field did not invert (it decreased to a value on the order of pT and then rose again)
In the “No inversion #2” experiment, the solution did not pass through the inversion chamber.

| | | | | No | No |
|---|---|---|---|---|---|
| | Coupling - | Inversion | Inversion | inversion | inversion |
| | J (Hz) | #1 | #2 | #1 | #2 |
| ¹³C-formate | 195 | 9.0% | 12.3% | 1.3% | 1.1% |
| [3-¹³C]- | 125 | 11.2% | 10.4% | 3.6% | 3.9% |
| pyruvate | | | | | |
| [2-¹³C]- | 6.2 | 0 | 0 | 0 | 0 |
| pyruvate | | | | | |
| [1-¹³C]- | 1.3 | 0 | 0 | 0 | 0 |
| pyruvate | | | | | |

Given the magnetic field profile of the inversion chamber and given the solution velocity, numerical spin dynamics simulations predict that polarization transfer from ¹H to ¹³C must be total for ¹³C-formate and [3-¹³C]-pyruvate. On the other hand, transfer is expected to be almost zero for [2-¹³C]-pyruvate and [1-¹³C]-pyruvate molecules because their J coupling is too weak (for the given field profile). Our experimental results confirm these predictions.

The two control experiments show that there was a non-zero transfer even without field inversion. This is probably due to the nuclear Overhauser effect (NOE) on the transfer in liquid. This transfer does not take place in [2-¹³C]-pyruvate and [1-¹³C]-pyruvate molecules, as the distance between the nuclear spins of ¹H and ¹³C is too great.

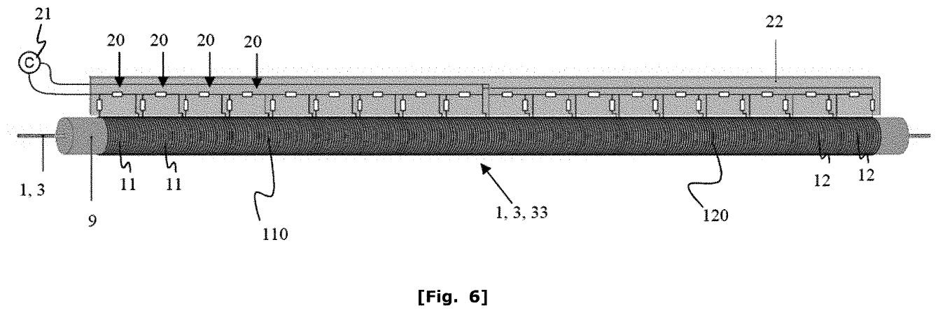

An implementation detail of the device 200 varies from the implementation detail of the device 100 in that:
all solenoids 11, 12 are made of copper wire, wire diameter 0.5 mm, coil diameter 4 cm, 62 coils, solenoid length 3 cm
the current source 21 supplies a current I of 4000 pA for ¹³C-formate molecules or 30 μA for 1-¹³C-pyruvate at the inlet of the current divider bridges 20,
the assembly 110 comprises 12 solenoids 11 with 12 current dividers 20 (a larger number than shown in FIG. 6),
the assembly 120 comprises twelve solenoids 12 with twelve current dividers 20 (a larger number than shown in FIG. 6),
each solenoid 11 or 12, associated with its current divider bridge 20 having resistors R₁ and R₂, has a current i₁=I(R₂/(R₁+R₂)) flowing through it
Each pair R1/R2 is different so that each solenoid portion 11 or 12 provides the optimum field 6. Each resistor has a default value set at 1000 Ohm for R₂ and for R₁ at a value increasing towards the center of portion 33 (increasing value for the bridges 20 from left to right for the assembly 110 and from right to left for the assembly 120). Typically, each resistor Ri has a value of 4 Ohm, 20 Ohm, 44 Ohm, 70 Ohm, 90 Ohm, 125 Ohm, 166 Ohm, 220 Ohm, 302 Ohm, 454 Ohm, 768 Ohm, 2000 Ohm for the 12 bridges 20 from left to right for assembly 110 and for the 12 bridges 20 from right to left for assembly 120.

The method according to the invention is applicable to a solution 1 comprising a molecule with a J coupling such as [2-¹³C]-pyruvate or [1-¹³C]-pyruvate.

The method according to the invention is applicable to a solution 1 comprising a molecule with a strong J coupling ([3-¹³C]-pyruvate, J=125 Hz), or other molecules more interesting for in vivo applications such as [2-¹³C]-pyruvate or [1-¹³C]-pyruvate whose couplings are around 1.3 and 6.2 Hz, respectively, more efficiently with a longer screen 5 (of the order of Im in length).

Of course, the invention is not limited to the examples just described, and many adjustments can be made to these examples without going beyond the scope of the invention.

The inversion portion 33 can be of any shape, straight, curved or a combination of curve(s) and/or straight line(s).

Of course, the various features, forms, variants and embodiments of the invention may be combined with each other in various combinations as long as they are not incompatible or exclusive of each other. In particular, all the variants and embodiments described above can be combined with each other.

1-14. (canceled)

15. A hyperpolarization method, comprising:
providing a solution in the liquid state comprising:
a first type of nuclear spins that are hyperpolarized and with a first gyromagnetic ratio, and
a second type of nuclear spins with a second gyromagnetic ratio;
the nuclear spins of both types being coupled by scalar spin-spin coupling in one or more molecules of solution;
supplying the solution to an inversion chamber so that this solution circulates in the form of a solution flow in a conduit of which a portion called the inversion portion passes through the inversion chamber; the inversion chamber comprising an inlet through which the solution flow enters and an outlet through which the solution flow exits; the inversion chamber comprising a magnetic screen which surrounds the inversion portion so as to isolate the inversion from ambient magnetic fields around the magnetic screen; and
creating, by at least one internal magnetization means located at least partially inside the magnetic screen, an inversion magnetic field having a main component along a direction Z, which inverts as traveling through the inside of the inversion portion so as to transfer, within the inversion portion, the hyperpolarization from the first type of nuclear spins to the second type of nuclear spins during a solution flow with non-zero velocity in the inversion portion from the chamber inlet to the chamber outlet.

16. The method according to claim 15, wherein the at least one internal magnetization means comprises, at least partially within the magnetic screen, a pair of internal magnetization means at least partially surrounding or framing or skirting the inversion portion, each internal magnetization means producing a magnetic field that is constant over time and is opposite to the field of the other internal magnetization means, the sum of the fields of the pair of internal magnetization means inverting within, preferably at the center of, the inversion portion.

17. The method according to claim 15, wherein the at least one internal magnetization means comprises, at least in part within the magnetic screen, multiple internal solenoids, at least partially surrounding the inversion portion and connected by current divider bridges, the internal solenoids being separated into two assemblies of internal solenoids powered by currents of opposite direction of rotation and whose leakage fields oppose each other.

18. The method according to claim 17, wherein the at least one internal magnetization means does not comprise a gap between the two assemblies of internal solenoids.

19. The method according to claim 17, wherein the current divider bridges comprise variable resistors via an adjustment interface, the method comprising a variation of the resistors of the divider bridges via this interface so as to adjust or optimize the magnetic field inversion profile.

20. The method according to claim 15, wherein the inversion chamber further comprises a magnetization means, called an external inlet magnetization means, at least partially outside the magnetic screen and extending at least as far as the inlet of the inversion chamber, and a magnetization means, called an external outlet magnetization means, at least partially outside the magnetic screen and extending at least as far as the outlet of the inversion chamber, each external magnetization means maintaining within the conduit an input magnetic field at the inlet of the inversion chamber and an output magnetic field at the outlet of the inversion chamber.

21. The method according to claim 20, wherein each external magnetization means surrounds or frames or skirts at least part of the at least one internal magnetization means.

22. The method according to claim 20, wherein each external magnetization means comprises or is an external solenoid, each external solenoid being carried around the conduit, surrounding the conduit, by means of an external support piece that:
on the conduit side, is not in contact with the conduit, and
on the side of each external solenoid, comprises reliefs arranged to accommodate and position the turns of each external solenoid.

23. The method according to claim 15, wherein the at least one internal magnetization means is at least one internal solenoid, each internal solenoid being carried at least in part by the inversion portion, surrounding the inversion portion at least in part, via an internal support piece that:
on the conduit side, is in contact with the conduit, and
on the side of each internal solenoid, comprises reliefs arranged to accommodate and position the turns of each internal solenoid along the conduit.

24. The method according to claim 15, wherein supplying the solution to the inversion chamber comprises supplying the solution from a dynamic nuclear polarization (DNP) device connected to the conduit.

25. The method according to claim 15, wherein inversion portion and/or the conduit is a capillary whose largest dimension, perpendicular to the solution flow, is less than 5 mm.

26. The method according to claim 15, wherein, in the inversion portion, the inversion magnetic field is comprised, in absolute value along the direction Z, at least between 0 mT and 0.1 mT.

27. A hyperpolarization device, comprising an inversion chamber, said inversion chamber, comprising:
an inlet arranged so that a flow of a solution in the liquid state, the solution comprising:
a first type of nuclear spins that are hyperpolarized and with a first gyromagnetic ratio and
a second type of nuclear spins with a second gyromagnetic ratio, the nuclear spins of both types being coupled by scalar spin-spin coupling in one or more molecules of the solution,
enters the chamber through the inlet;
an outlet arranged so that the solution flow leaves the chamber through the outlet, the inlet and outlet being arranged so that this solution flows according to the solution flow within a conduit, a portion of which, called the inversion portion, passes through the inversion chamber;
a magnetic screen surrounding the inversion portion to isolate the inversion portion from ambient magnetic fields around the magnetic screen; and
at least one internal magnetization means located at least partially inside the magnetic screen, arranged to create an inversion magnetic field having a main component along a direction Z that inverts as the main component travels through the inside of the inversion portion so as to transfer, within the inversion portion, the hyperpolarization from the first type of nuclear spins to the second type of nuclear spins during a solution flow with non-zero velocity in the inversion portion from the chamber inlet to the chamber outlet; and
a device arranged to supply the solution to the inlet of the inversion chamber via the conduit.

28. The hyperpolarization device according to claim 27, wherein the device arranged to supply the solution to the inlet of the inversion chamber comprises a dynamic nuclear polarization (DNP) device connected to the conduit.
